(19) United States
(12) Patent Application Publication
(10) Pub. No.: US 2025/0022725 A1
(43) Pub. Date: Jan. 16, 2025

(54) GAS DISTRIBUTION ELEMENT AND HEAT TREATMENT DEVICE CONTAINING THE SAME

(71) Applicant: Beijing E-Town Semiconductor Technology Co., Ltd., Beijing (CN)

(72) Inventors: Jianmin JI, Beijing (CN); Haiwei LI, Beijing (CN); Wenyi LI, Beijing (CN)

(21) Appl. No.: 18/752,859

(22) Filed: Jun. 25, 2024

(30) Foreign Application Priority Data
Jul. 13, 2023 (CN) 202310861652.3

(51) Int. Cl. H01L 21/67

(52) U.S. Cl. CPC H01L 21/67109

(57) ABSTRACT

Provided is a gas distribution element and a heat treatment device containing the gas distribution element. The gas distribution element comprises at least two regions with different hole distribution densities. Specifically, the gas distribution element comprises a first region defined by a first distance radially extending outward from a geometric center, and a second region defined by a second distance radially extending from an outermost edge toward the geometric center; and the first region and the second region respectively have holes with different distribution densities.

### CROSS-REFERENCE TO RELATED APPLICATIONS

The present application claims priority to Chinese Patent Application No. CN202310861652.3, filed with the China National Intellectual Property Administration on Jul. 13, 2023, the disclosure of which is hereby incorporated herein by reference in its entirety.

### TECHNICAL FIELD

The present invention relates to the field of semiconductor manufacturing, and in particular to a gas distribution element and a heat treatment device containing the gas distribution element.

### BACKGROUND

In the current atmospheric pressure annealing equipment, the gas intake mode may be that the gas enters from the top of the reaction chamber, from the side of the reaction chamber, or from both the top and the side. However, the above-mentioned gas intake mode usually cannot meet the process requirement due to the small amount of gas in a low-pressure equipment.

### SUMMARY

The present invention provides a gas distribution element and a heat treatment device containing the gas distribution element.

According to one aspect of the present invention, provided is a gas distribution element, including at least two regions with different hole distribution densities. Here, the gas distribution element includes a first region defined by a first distance radially extending outward from a geometric center, and a second region defined by a second distance radially extending from an outermost edge toward the geometric center; and the first region and the second region respectively have holes with different distribution densities.

According to another aspect of the present invention, provided is a heat treatment device, including the above-mentioned gas distribution element. Here, the gas distribution element is arranged on an inner side of a side wall at a gas inlet end of the heat treatment device.

It should be understood that the content described in this part is not intended to identify critical or essential features of embodiments of the present invention, nor is it used to limit the scope of the present invention. Other features of the present invention will be easily understood through the following description.

### BRIEF DESCRIPTION OF THE DRAWINGS

The accompanying drawings are used to better understand the present solution, and do not constitute a limitation to the present invention.

FIG. 1 is a cross-sectional view of a gas distribution element in the prior art;

FIG. 2 is a cross-sectional view of a gas distribution element according to one embodiment of the present invention;

FIG. 3 is a cross-sectional view of a gas distribution element according to another embodiment of the present invention; and

FIG. 4 is a cross-sectional view of a gas distribution element according to yet another embodiment of the present invention.

### DETAILED DESCRIPTION

Hereinafter, descriptions to exemplary embodiments of the present disclosure are made with reference to the accompanying drawings, include various details of the embodiments of the present disclosure to facilitate understanding, and should be considered as merely exemplary. Therefore, those having ordinary skill in the art should realize, various changes and modifications may be made to the embodiments described herein, without departing from the scope of the present disclosure. Likewise, for clarity and conciseness, descriptions of well-known functions and structures are omitted in the following descriptions.

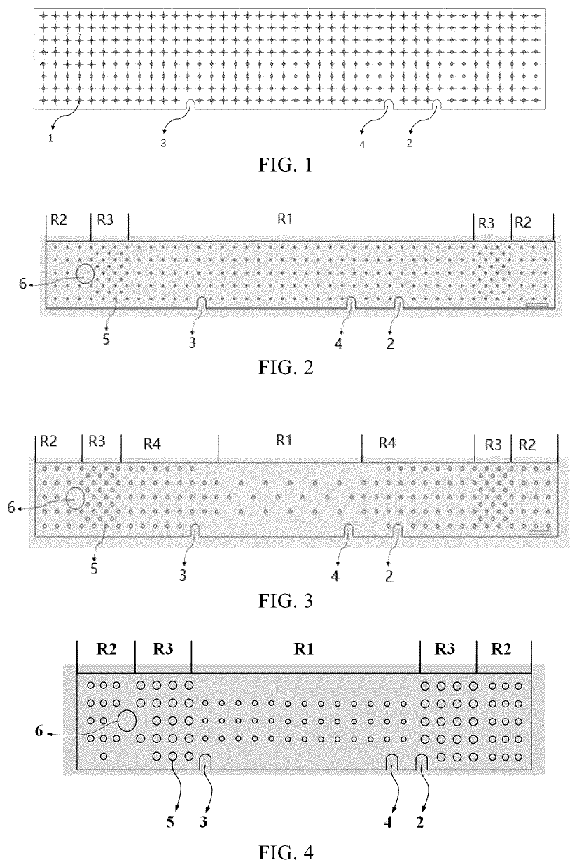

In a low-pressure heat treatment device used for semiconductor workpieces, due to the relatively low pressure, such as 1 to 20 Torr, the amount of gas in the equipment is relatively small, so the gas flow is easily unevenly distributed, which has a greater impact on the process. Similarly, as shown in FIG. 1, when the low-pressure equipment adopts side gas intake, a gas intake plate is usually arranged on the side of the low-pressure equipment in the prior art, and the gas intake plate is provided with holes 1 with uniform spacing and consistent aperture, and a plurality of avoidance slots 2, 3 and 4 are provided at the edge. If the gas intake holes are designed to be uniform, the gas flow distributions at the center and edge of the wafer will be different, so that the process uniformity does not meet the requirement. Therefore, based on the cavity of the annealing equipment, the design of a grid gas intake distribution plate with uneven gas intake can solve the problem of uniformity in the low-pressure process.

### Gas Distribution Element

The present invention provides a gas distribution element, which may include at least two regions with different hole distribution densities. Further, the gas distribution element may include a first region defined by a first distance radially extending outward from a geometric center, and a second region defined by a second distance radially extending from an outermost edge toward the geometric center. Also, the first region and the second region respectively have holes with different distribution densities.

According to one embodiment, the above-mentioned gas distribution element may be disposed inside one side end of the heat treatment device, that is, the gas intake mode of the heat treatment device may include gas intake from the side, or gas intake from the side and top. Further, the gas distribution element may be made of any stable material suitable for use in a reaction chamber of a semiconductor heat treatment device, and preferably made of a transparent quartz plate with predetermined hole distribution.

FIG. 2 is a schematic cross-sectional view of a gas distribution element according to one embodiment of the present disclosure. The gas distribution element includes a plurality of regions R1, R2 and R3 having holes 5 with different distribution densities; an avoidance region 6 for avoiding other gas intake pipes; and avoidance slots 2, 3 and 4 for avoiding a gas flotation block, an acceleration block and a deceleration block respectively.

Here, the gas distribution element includes a central region, i.e., a first region R1 defined by a first distance radially extending outward from a geometric center of the gas distribution element. For example, in the first region, the first distance may be 1 to 50 mm, preferably 3 to 45 mm, and more preferably 5 to 40 mm, and may be, for example, 8 mm, 10 mm, 15 mm, 20 mm, 25 mm, 30 mm, 35 mm or 40 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the distribution density of the holes in the first region may be such that the distance between the circle centers of adjacent holes is 1.4 to 2 cm, and may be, for example, 1.5 cm, 1.6 cm, 1.7 cm, 1.8 cm or 1.9 cm.

According to one embodiment, the above-mentioned gas distribution element may further include an outermost region, i.e., a second region R2 defined by a second distance radially extending from the gas distribution element toward the geometric center thereof. For example, in the second region, the second distance may be 30 to 50 mm, preferably 32 to 45 mm, and more preferably 35 to 43 mm, and may be, for example, 37 mm, 38 mm, 39 mm, 40 mm, 41 mm or 42 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the distribution density of the holes in the second region is greater than the distribution density of the holes in the first region. For example, the distance between the circle centers of adjacent holes may be 1 cm.

According to one embodiment, the gas distribution element may further include an intermediate region between the first region and the second region, i.e., a third region R3, and the holes in this region may have the same aperture, for example, in the range of 1 to 10 mm, preferably 2 to 8 mm, for example, 3 mm, 4 mm, 5 mm, 6 mm or 7 mm.

According to one embodiment, the distribution density of holes in the third region may be greater than the distribution density of the holes in the first region and less than the distribution density of the holes in the second region. For example, the distance between the circle centers of adjacent holes may be about 0.5 cm.

In order to ensure that a uniform gas flow can be formed in the reaction chamber, the hole densities in different regions of the gas distribution element need to be set according to a certain ratio. Specifically, the ratio of the hole densities of the first region and the third region may be 1:(2-8), for example, 1:3, 1:4, 1:5, 1:6, 1:7. Further, the ratio of the hole densities of the first region and the second region may be 1:(2-4), for example, 1:3. Also, the hole density of the third region is greater than the hole density of the second region.

For the low-pressure heat treatment device of the present invention, in order to maintain the low-pressure environment, the amount of gas input into the reaction chamber of the heat treatment device is relatively small, which easily causes the gas flow distribution in the central region of the chamber to be greater than that in the edge region, so that the oxidation product grows faster in the central region of the surface of the semiconductor workpiece (such as silicon wafer) and grows slower in the edge region, and thus the thickness of a finally-formed oxide layer in the central region is greater than that in the edge region. Therefore, the gas distribution element according to the present invention is arranged at the side end of the reaction chamber and has holes with different distribution densities, especially holes with sparse distribution in the center and dense distribution at the edge, so as to provide the uniform gas flow in the reaction chamber, thereby forming the oxide layer with high uniformity and few defects on the surface of the semiconductor workpiece during the heat treatment process, and shortening the oxidation treatment time.

FIG. 3 is a schematic cross-sectional view of a gas distribution element according to another embodiment of the present disclosure. The gas distribution element includes a plurality of regions R1, R2, R3 and R4 having holes 5 with different distribution densities; an avoidance region 6 for avoiding other gas intake pipes; and avoidance slots 2, 3 and 4 for avoiding a gas flotation block, an acceleration block and a deceleration block respectively.

Here, the gas distribution element includes a central region, i.e., a first region R1 defined by a first distance radially extending outward from a geometric center of the gas distribution element. For example, in the first region, the first distance may be 1 to 50 mm, preferably 3 to 45 mm, and more preferably 5 to 40 mm, and may be, for example, 8 mm, 10 mm, 15 mm, 20 mm, 25 mm, 30 mm, 35 mm or 40 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the distribution density of the holes in the first region may be such that the distance between the circle centers of adjacent holes is 1.4 to 2 cm, and may be, for example, 1.5 cm, 1.6 cm, 1.7 cm, 1.8 cm or 1.9 cm.

According to one embodiment, the above-mentioned gas distribution element may further include an outermost region, i.e., a second region R2 defined by a second distance radially extending from the gas distribution element toward the geometric center thereof. For example, in the second region, the second distance may be 30 to 50 mm, preferably 32 to 45 mm, and more preferably 35 to 43 mm, and may be, for example, 37 mm, 38 mm, 39 mm, 40 mm, 41 mm or 42 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the distribution density of the holes in the second region is greater than the distribution density of the holes in the first region. For example, the distance between the circle centers of adjacent holes may be 1 cm.

According to one embodiment, the gas distribution element may further include at least two intermediate regions between the first region and the second region, i.e., a third region R3 and a fourth region R4, and the holes in the same region may have the same aperture, for example, in the range of 1 to 10 mm, preferably 2 to 8 mm, for example, 3 mm, 4 mm, 5 mm, 6 mm or 7 mm.

According to one embodiment, the distribution density of holes in the third region may be greater than the distribution density of the holes in the first region and less than the distribution density of the holes in the second region. For example, the distance between the circle centers of adjacent holes may be about 0.5 cm.

According to one embodiment, the distribution density of holes in the fourth region may be greater than the distribution density of holes in the first region, less than or equal to the distribution density of holes in the second region, and less than the distribution density of holes in the third region. For example, the distance between the circle centers of adjacent holes may be about 1 cm.

In order to ensure that a uniform gas flow can be formed in the reaction chamber, the hole densities in different regions of the gas distribution element need to be set according to a certain ratio. Specifically, the ratio of the hole densities of the first region and the third region may be 1:(2-8), for example, 1:3, 1:4, 1:5, 1:6, 1:7. Further, the ratio of the hole densities of the first region and the second region may be 1:(2-4), for example, 1:3. The ratio of the hole densities of the first region and the fourth region may be 1:(2-4), for example, 1:3. Also, the hole density of the third region is greater than the hole density of the second region, the hole density of the fourth region is less than the hole density of the third region, and the hole density of the second region and the hole density of the fourth region may be the same or different.

As shown in FIG. 4, the gas distribution element according to a third embodiment of the present disclosure includes a plurality of regions R1, R2 and R3 having holes 5 with different apertures; an avoidance region 6 for avoiding other gas intake pipes; and avoidance slots 2, 3 and 4 for avoiding a gas flotation block, an acceleration block and a deceleration block respectively. According to a specific embodiment, the aperture spacings among these regions are different.

Here, the gas distribution element includes a central region, i.e., a first region R1 defined by a first distance radially extending outward from a geometric center of the gas distribution element. For example, in the first region, the first distance may be 1 to 50 mm, preferably 3 to 45 mm, and more preferably 5 to 40 mm, and may be, for example, 8 mm, 10 mm, 15 mm, 20 mm, 25 mm, 30 mm, 35 mm or 40 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the distribution density of the holes in the first region may be such that the distance d1 between the circle centers of adjacent holes may be 1.4 to 2 cm, and may be, for example, 1.5 cm, 1.6 cm, 1.7 cm, 1.8 cm or 1.9 cm.

According to one embodiment, the above-mentioned gas distribution element may further include an outermost region, i.e., a second region R2 defined by a second distance radially extending from an outermost edge of the gas distribution element toward the geometric center thereof. For example, in the second region, the second distance may be 30 to 50 mm, preferably 32 to 45 mm, and more preferably 35 to 43 mm, and may be, for example, 37 mm, 38 mm, 39 mm, 40 mm, 41 mm or 42 mm; and the holes in this region may have the same aperture, for example, in the range of 1 to 10 mm, preferably 2 to 8 mm, for example 3 mm, 4 mm, 5 mm, 6 mm or 7 mm.

According to one embodiment, the inner diameter of the hole in the second region is greater than the inner diameter of the hole in the first region. For example, the distance d2 between the circle centers of adjacent holes may be 1 cm. Preferably, the inner diameter of the hole in the second region may be 1 to 7 mm.

According to one embodiment, the gas distribution element may further include an intermediate region between the first region and the second region, i.e., a third region R3, and the holes in this region may have the same aperture, for example, in the range of 1 to 10 mm, preferably 2 to 8 mm, for example, 3 mm, 4 mm, 5 mm, 6 mm or 7 mm.

According to one embodiment, the inner diameter of the hole in the third region may be greater than the inner diameter of the hole in the first region and greater than the inner diameter of the hole in the second region. For example, the distance d3 between the circle centers of adjacent holes may be about 0.5 cm. Preferably, the inner diameter of the hole in the second region may be 1 to 2 mm.

In order to ensure that a uniform gas flow can be formed in the reaction chamber, the changes of the inner diameters of the holes in different regions of the gas distribution element need to be set according to a certain ratio. Specifically, the ratio of the inner diameters of the holes in the first region and the third region may be 1:(2-8), for example, 1:3, 1:4, 1:5, 1:6, 1:7. Further, the ratio of the inner diameters of the holes in the first region and the second region may be 1:(2-4), for example, 1:3.

Further, the gas distribution element according to a fourth embodiment of the present invention, based on the gas distribution element of the third embodiment mentioned above, may further include a fourth region R4 located between the third region and the first region, and the holes in this region may have the same aperture, for example, in the range of 1 to 10 mm, preferably 2 to 8 mm, for example 3 mm, 4 mm, 5 mm, 6 mm or 7 mm.

Specifically, the ratio of the inner diameters of the holes in the first region and the third region may be 1:(2-8), for example, 1:3, 1:4, 1:5, 1:6, 1:7. Further, the ratio of the inner diameters of the holes in the first region and the second region may be 1:(2-4), for example, 1:3. The ratio of the inner diameters of the holes in the first region and the fourth region may be 1:(2-4), for example, 1:3. Also, the inner diameter of the hole in the third region is greater than the inner diameter of the hole in the second region, the inner diameter of the hole in the fourth region is less than the inner diameter of the hole in the third region, and the inner diameter of the hole in the second region and the inner diameter of the hole in the fourth region may be the same or different. The distance d4 between the circle centers of adjacent holes in the fourth region may be 0.5 cm.

In the third embodiment above, according to one specific example, when the inner diameter of the hole changes, the distance between the circle centers of the holes can be kept unchanged. The change in the inner diameter of the hole causes the gap between adjacent holes to change. Specifically, considering the gap between holes, it is preferred that the gap between adjacent holes should be maintained at more than 3 mm, that is, the minimum width of the quartz material between adjacent holes is more than 3 mm.

According to another specific example, when the inner diameter of the hole changes, the gap between adjacent holes remains unchanged, that is, the distance between the circle centers of adjacent holes changes, but the distance between the circle centers meets the above requirement.

According to the embodiments described above, the gas distribution element of the present invention can adjust the inner diameters of the holes in different regions to have a similar effect of adjusting the density of the holes, so that the gas entering the reaction chamber can form a uniform gas flow, and thus the surface of the semiconductor workpiece (such as wafer) exposed to the gas flow can be uniformly oxidized to form an oxide film layer with uniform thickness, and the defects in the film layer are reduced, thereby increasing the rate of oxidation treatment and improving the production efficiency.

### Heat Treatment Device

According to one embodiment of the present invention, provided is a heat treatment device for performing heat treatment, such as oxidation treatment, on a semiconductor workpiece, and the heat treatment device includes the above-mentioned gas distribution element. According to one embodiment, the gas distribution element is arranged on an inner side of a side wall at a gas inlet end of the heat treatment device. Correspondingly, a gas outlet is arranged at the other end opposite to the end where the gas distribution element is located.

According to another embodiment, in addition to the gas distribution element arranged at one end, a gas inlet may be arranged at the top of the heat treatment device.

When the heat treatment device with the above-mentioned gas inlet arrangement is used for a low-pressure heat treatment process of a semiconductor workpiece, the process temperature may be 600 to 1200° C., and the process gas pressure in the reaction chamber of the heat treatment device may be a low pressure of 1 to 20 Torr.

According to a specific embodiment, the process gas may include hydrogen and oxygen. Here, based on the total flow rate of the process gas, the flow rate ratio of hydrogen may be less than 30% and not 0%, and the flow rate ratio of oxygen may be greater than 70% and not 100%.

The heat treatment device according to the present invention may be used as a low-pressure treatment device for rapid heat treatment, or may be used as a remote plasma treatment device.

It should be understood that, the steps may be reordered, added or removed by using the various forms of the flows described above. For example, the steps recorded in the present disclosure can be performed in parallel, in sequence, or in different orders, as long as a desired result of the technical scheme disclosed in the present disclosure can be realized, which is not limited herein.

The foregoing specific implementations do not constitute a limitation on the protection scope of the present disclosure. Those having ordinary skill in the art should understand that, various modifications, combinations, sub-combinations and substitutions may be made according to a design requirement and other factors. Any modification, equivalent replacement, improvement or the like made within the principle of the present disclosure shall be included in the protection scope of the present disclosure.

What is claimed is:

1. A gas distribution element, comprising at least two regions with different hole distribution densities.

2. The gas distribution element of claim 1, wherein the gas distribution element comprises a first region defined by a first distance radially extending outward from a geometric center, and a second region defined by a second distance radially extending from an outermost edge toward the geometric center; and
the first region and the second region respectively have holes with different distribution densities.

3. The gas distribution element of claim 2, further comprising at least one third region located between the first region and the second region, wherein the third region has a hole distribution density different from those of the first region and the second region.

4. The gas distribution element of claim 2, wherein a ratio of the hole distribution densities of the first region and the second region is 1:(2-4).

5. The gas distribution element of claim 3, wherein a ratio of the hole distribution densities of the first region and the third region is 1:(2-8).

6. The gas distribution element of claim 2, wherein inner diameters of the holes are 1 to 10 mm.

7. The gas distribution element of claim 2, wherein inner diameters of the holes are different in different regions.

8. The gas distribution element of claim 6, wherein the inner diameters of the holes are different in different regions.

9. A heat treatment device, comprising a gas distribution element, wherein the gas distribution element comprises at least two regions with different hole distribution densities.

10. The heat treatment device of claim 9, wherein the gas distribution element is arranged on an inner side of a side wall at a gas inlet end of the heat treatment device.

11. The heat treatment device of claim 9, wherein the gas distribution element comprises a first region defined by a first distance radially extending outward from a geometric center, and a second region defined by a second distance radially extending from an outermost edge toward the geometric center; and
the first region and the second region respectively have holes with different distribution densities.

12. The heat treatment device of claim 11, wherein the gas distribution element further comprises at least one third region located between the first region and the second region, wherein the third region has a hole distribution density different from those of the first region and the second region.

13. The heat treatment device of claim 11, wherein a ratio of the hole distribution densities of the first region and the second region is 1:(2-4).

14. The heat treatment device of claim 13, wherein a ratio of the hole distribution densities of the first region and the third region is 1:(2-8).

15. The heat treatment device of claim 11, wherein inner diameters of the holes are 1 to 10 mm.

16. The heat treatment device of claim 11, wherein inner diameters of the holes are different in different regions.

17. The heat treatment device of claim 16, wherein the inner diameters of the holes are different in different regions.
